(19) United States
(12) Patent Application Publication
(10) Pub. No.: US 2025/0174565 A1
(43) Pub. Date: May 29, 2025

(54) EMBEDDED THREE-DIMENSIONAL FAN-OUT PACKAGE STRUCTURE AND PREPARATION METHOD THEREOF

(71) Applicant: SHENZHEN XIUYUAN ELECTRONIC TECHNOLOGY CO., LTD., Shenzhen (CN)

(72) Inventors: Wei ZHENG, Guangzhou (CN); Yingqiang YAN, Guangzhou (CN); Yao WANG, Guangzhou (CN); Xun XIANG, Guangzhou (CN); Yinhua CUI, Guangzhou (CN); Yunzhi LING, Guangzhou (CN); Siliang HE, Guangzhou (CN); Chuan HU, Guangzhou (CN); Zhitao CHEN, Guangzhou (CN)

(73) Assignee: SHENZHEN XIUYUAN ELECTRONIC TECHNOLOGY CO., LTD., Shenzhen, GD (CN)

(21) Appl. No.: 19/038,096

(22) Filed: Jan. 27, 2025

Related U.S. Application Data
(63) Continuation-in-part of application No. PCT/CN2022/112590, filed on Aug. 15, 2022.

(51) Int. Cl. H01L 23/538; H01L 21/48; H01L 21/56; H01L 21/683; H01L 23/00; H01L 23/053; H01L 23/08; H01L 23/29; H01L 23/31; H01L 23/367; H01L 23/373; H01L 23/498; H01L 25/065

(52) U.S. Cl. CPC H01L 23/5383; H01L 21/4853; H01L 21/4857; H01L 21/4875; H01L 21/568; H01L 21/6835; H01L 23/053; H01L 23/08; H01L 23/293; H01L 23/3128; H01L 23/3675; H01L 23/3736; H01L 23/49838; H01L 23/49866; H01L 23/5386; H01L 24/32; H01L 25/0655; H01L 2224/32225; H01L 2924/1815

(57) ABSTRACT

Provided are embedded three-dimensional fan-out package structure and method. In one example, the method includes: fabricating chip module based on a multi-faceted pin chip, bonding chip module and additional chip to temporary carrier; forming plastic packaging layer on side of temporary carrier; removing temporary carrier; forming redistribution layer on plastic packaging layer; and forming electrically conductive solder balls or bumps on side of protective dielectric layer in redistribution layer facing away from chip module and additional chip, wherein they pass through protective dielectric layer to be electrically connected to upper pins of electrically conductive wiring layer.

### CROSS-REFERENCE TO RELATED APPLICATION

This Utility patent application is a continuation-in-part of International Application Serial No. PCT/CN2022/112590, filed Aug. 15, 2022, which is incorporated herein by reference in its entirety.

### TECHNICAL FIELD

The present disclosure relates to the technical field of semiconductor packaging. More specifically, the present disclosure relates to an embedded three-dimensional fan-out package structure and a preparation method thereof.

### BACKGROUND ART

With the arrival of 5G era, data processed by a system are sharply increased, which requires electronic devices to have a faster processing speed and a higher Data transmission bandwidth. In contrast, as the chip technologies move towards 7 nm, 5 nm, 3 nm, or even more advanced, quantum tunneling effect makes it quite difficult for transistor miniaturization. The entire semiconductor industry feels the physical limit approaching. It is becoming increasingly difficult and expensive to accommodate more chips on a single-chip integrated circuit. For this reason, the semiconductor industry seeks a variety of technical solutions to improve cost performance while adding more functions through integration. In this case, an advanced packaging technology has become a direction of interest for researchers. The advanced packaging technology is considered as an effective method for further improving computing power density. The advanced packaging does not adopt the conventional packaging process, for example, the advanced packaging generally does not adopt a bonding wire that is most commonly used in the conventional packaging, and therefore, the advanced packaging has a quite high integration degree and a very small packaging volume. In addition, interconnection lines in the advanced packaging are quite short, and system performance is much improved.

In recent years, the advanced packaging technology continues to break through and develop with requirements of high performance, small dimension, high reliability and ultra-low power consumption in chips and electronic devices, and meanwhile are developing towards system integration, high speed, high frequency, and three-dimensional directions with the development of artificial intelligence, automatic driving, 5G network, the Internet of Things and other emerging industries. Particularly, there is an increasingly strong demand for three-dimensional (3D) integration advanced packaging. Therefore, the advanced packaging technology continues to innovate and develop, so as to meet the need for more complex three-dimensional integration. At present, high-density through silicon via (TSV) technology/fan-out packaging technology has now become a core technology for advanced packaging due to its flexibility, high density, and suitability for system integration. However, TSV technology is complicated process, High cost and poor in heat dissipation.

The present disclosure does not use TSV technology, and adopts fan-out packaging technology to simplify the process, reduce the cost, and have better heat dissipation performance

### SUMMARY

The present disclosure provides a preparation method for preparing an embedded three-dimensional fan-out package structure, wherein the preparation method includes the following steps: providing a multi-faceted pin chip, wherein pins of the multi-faceted pin chip are distributed in different positions of multiple side surfaces of the multi-faceted pin chip; fabricating a chip module based on the multi-faceted pin chip, wherein pins of the chip module are located in the same plane; bonding the chip module and an additional chip to a temporary carrier in a flip chip manner, so that the pins of the chip module and pins of the additional chip are located in the same plane and are connected to the same surface of the temporary carrier; forming a plastic packaging layer on a side of the temporary carrier bonded with the chip module and the additional chip, so that the chip module and the additional chip are embedded in the plastic packaging layer; removing the temporary carrier, so that the pins of the chip module and the pins of the additional chip are exposed from a first surface of the plastic packaging layer; forming a redistribution layer on the first surface of the plastic packaging layer, wherein the redistribution layer includes a wiring dielectric layer adjacent to the plastic packaging layer, a protective dielectric layer provided on a side of the wiring dielectric layer facing away from the chip modules and the additional chips, as well as an electrically conductive wiring layer embedded in the wiring dielectric layer and the protective dielectric layer and electrically connected to the chip module and the additional chip, and wherein the electrically conductive wiring layer includes: lower pins respectively electrically connected to the pins of the chip module and the pins of the additional chip, interconnection lines connecting the pins of the chip module and the pins of the additional chip, first metal pillars respectively extending from the lower pins and the interconnection lines in a direction facing away from the chip module and the additional chip and electrically connected to corresponding lower pins and interconnection lines, as well as upper pins each formed at an end of the first metal pillars away from the chip module and the additional chip and electrically connected to the first metal pillars; and forming electrically conductive solder balls and/or bumps on a side of the protective dielectric layer in the redistribution layer facing away from the chip module and the additional chip, wherein the electrically conductive solder balls and/or bumps pass through the protective dielectric layer to be electrically connected to the upper pins of the electrically conductive wiring layer.

The present disclosure further provides an embedded three-dimensional fan-out package structure, wherein the embedded three-dimensional fan-out package structure includes: a plastic packaging layer, wherein the plastic packaging layer includes a first surface and a second surface opposite to the first surface; a chip module and an additional chip embedded in the first surface of the plastic packaging layer, wherein the chip module includes multi-faceted pin chips, the multi-faceted pin chips have pins distributed in different positions of multiple side surfaces, the pins of the multi-faceted pin chips are transferred into the same plane by guide metal pillars, so that pins of the chip modules and pins of the additional chips are located in the same plane as the first surface of the plastic packaging layer; a redistribution layer, wherein the redistribution layer is provided on the first surface of the plastic packaging layer, and the redistribution layer includes a wiring dielectric layer adjacent to the plastic packaging layer, a protective dielectric layer provided on a side of the wiring dielectric layer facing away from the chip modules and the additional chips, and an electrically conductive wiring layer embedded in the wiring dielectric layer and the protective dielectric layer and electrically connected to the chip module and the additional chip, and wherein the electrically conductive wiring layer includes: lower pins respectively electrically connected to the pins of the chip module and the pins of the additional chip, interconnection lines connecting the pins of the chip module and the pins of the additional chip, first metal pillars respectively extending from the lower pins and the interconnection lines in a direction facing away from the chip module and the additional chip and electrically connected to corresponding lower pins and the interconnection lines, as well as upper pins each formed at an end of the first metal pillars away from the chip module and the additional chip and electrically connected to the first metal pillars; and electrically conductive solder balls and/or bumps, wherein the electrically conductive solder balls and/or the bumps are provided on a side of the protective dielectric layer in the redistribution layer facing away from the chip module and the additional chip and pass through the protective dielectric layer to be electrically connected to the upper pins of the electrically conductive wiring layer.

### BRIEF DESCRIPTION OF DRAWINGS

In order to more clearly illustrate technical solutions of the present disclosure, drawings which need to be used therein are introduced briefly below. It should be understood that the drawings below merely show some embodiments of the present disclosure, and therefore, they should not be considered as limitation to the scope. Those ordinarily skilled in the art still could obtain other relevant drawings according to these drawings, without using any inventive efforts.

Through the following description with reference to the drawings, features and advantages of the embodiments of the present disclosure will become easier to understand. The drawings are not drawn to scale, and some features are enlarged or reduced so as to show details of particular components. In the drawings:

FIG. 1 is a schematic flowchart showing a preparation method for preparing an embedded three-dimensional fan-out package structure according to an exemplary embodiment of the present disclosure;

FIG. 2a to FIG. 2f are illustrative schematic diagrams showing fabrication of a chip module based on a multi-faceted pin chip according to an exemplary embodiment of the present disclosure;

FIG. 3a to FIG. 3f are illustrative schematic diagrams showing providing a heat dissipation frame and embedding the heat dissipation frame with a chip module and an additional chip in a plastic packaging layer according to an exemplary embodiment of the present disclosure;

FIG. 4a to FIG. 4e are illustrative schematic diagrams showing fabrication of a chip module based on a multi-faceted pin chip according to an exemplary embodiment of the present disclosure;

FIG. 5a to FIG. 5i are illustrative schematic diagrams showing fabrication of a chip module based on a multi-faceted pin chip according to an exemplary embodiment of the present disclosure;

FIG. 6 is a schematic flowchart showing formation of a redistribution layer on a first surface of a plastic packaging layer (step S160) in the preparation method as shown in FIG. 1;

FIG. 7a to FIG. 7h are illustrative schematic diagrams showing the formation of the redistribution layer on the first surface of the plastic packaging layer corresponding to various steps in the exemplary embodiment in FIG. 6 according to the present disclosure;

FIG. 8 shows a schematic sectional diagram of an embedded three-dimensional fan-out package structure including the chip module fabricated through a process as shown in FIG. 2a to FIG. 2f according to an exemplary embodiment of the present disclosure;

FIG. 9 shows a schematic sectional diagram of an embedded three-dimensional fan-out package structure obtained by embedding the heat dissipation frame in a plastic packaging layer with the chip module fabricated through a process as shown in FIG. 2a to FIG. 2f and an additional chip through a process as shown in FIG. 3a to FIG. 3f according to an exemplary embodiment of the present disclosure;

FIG. 10 shows a schematic sectional diagram of an embedded three-dimensional fan-out package structure including the chip module fabricated through a process as shown in FIG. 4a to FIG. 4e according to an exemplary embodiment of the present disclosure; and

FIG. 11 shows a schematic sectional diagram of an embedded three-dimensional fan-out package structure including the chip module fabricated through a process as shown in FIG. 5a to FIG. 5i and formed through a shown process according to an exemplary embodiment of the present disclosure.

Reference signs: 200—embedded three-dimensional fan-out package structure; 210—chip module; 2101—multi-faceted pin chip; 2102—supporting substrate; 2103—electrically conductive layer structure; 2104—first bonding adhesive layer; 2105—insulating frame; 2106—first groove; 2107—second groove; 2108—second metal pillar; 2109—metal lead; 2110—metal material layer; 2111—electrically conductive adhesive layer; 310—heat dissipation frame; 710—chip module accommodating groove; 711—chip accommodating groove; 712—chip module bonding adhesive layer; 712′—chip bonding adhesive layer; 220—chip; 100—temporary carrier; 230—plastic packaging layer; 2301—first surface; 210′—chip module; 2105′—insulating frame; 2106′—first groove; 2109′—metal lead; 2110′—metal material layer; 2111′—electrically conductive adhesive layer; 2112′—open end; 2114′—side wall; 210″—chip stack; 2106″—electrically conductive adhesive accommodating groove; 2107″—communicating hole; 2108″—guide metal pillar; 2111″—electrically conductive adhesive layer; 230″—plastic packaging layer; 2301″—first surface; 240—redistribution layer; 2401—lower pin; 2402—interconnection line; 2403—wiring dielectric layer; 2404—first through-hole; 2405—first metal pillar; 2406—upper pin; 2407—protective dielectric layer; 2408—blind via; 2409—electrically conductive solder ball; 2410—bump; 300—embedded three-dimensional fan-out package structure; 400—embedded three-dimensional fan-out package structure; 500—embedded three-dimensional fan-out package structure.

### DETAILED DESCRIPTION OF EMBODIMENTS

In order to make the objectives, technical solutions and advantages of embodiments of the present disclosure clearer, the technical solutions in the embodiments of the present disclosure will be described clearly and completely below in conjunction with the drawings in the embodiments of the present disclosure. Apparently, the embodiments described are some but not all embodiments of the present disclosure. Generally, components in the embodiments of the present disclosure, as described and shown in the drawings herein, may be arranged and designed in various different configurations.

Therefore, the following detailed description of the embodiments of the present disclosure provided in the drawings is not intended to limit the claimed scope of the present disclosure, but merely represents chosen embodiments of the present disclosure. All of other embodiments obtained by those ordinarily skilled in the art on the basis of the embodiments in the present disclosure without using any inventive efforts shall fall within the scope of protection of the present disclosure.

The present disclosure will be described in detail through exemplary embodiments with reference to the drawings. It is to be noted that the following detailed description of the present disclosure is merely for illustrative purpose, but is in no way limitation to the present disclosure. Besides, the same reference signs are used to denote the same components in various drawings. Besides, the drawings are not drawn to scale, and some features are enlarged or reduced so as to show details of particular components.

It should also be noted that, for the sake of clarity, not all of the features of actual specific embodiments are described and shown in the description and drawings, and furthermore, in order to avoid obscuring the technical solutions focused in the present disclosure with unnecessary details, only device structures closely related to the technical solutions of the present disclosure are described and shown in the drawings and the description, while other details of little relevance to the technical contents of the present disclosure and known to those skilled in the art are omitted.

Unless otherwise defined, all technical and scientific terms used herein have the same meaning as commonly understood by those skilled in the art to which the present disclosure belongs. The terms used herein are merely for the purpose of describing specific embodiments, but are not intended to limit the present disclosure. The terms “comprising (including)”, “having” and any variations thereof in the description and the claims of the present disclosure as well as in the above description of the drawings are intended to cover a non-exclusive inclusion.

In the description of the embodiments of the present disclosure, the technical terms such as “first” and “second” are merely used to distinguish different objects, but should not be construed as indicating or implying importance in the relativity or implicitly specifying the number, a particular order or relationship of priority of related technical features. In the description of the embodiments of the present disclosure, “multiple (a plurality of)” means two or more than two, unless otherwise defined explicitly and specifically.

Reference to “example/embodiment” herein means that particular features, structures or characteristics described in conjunction with an embodiment may be included in at least one embodiment of the present disclosure. The occurrence of these words in various positions in the description does not necessarily all refer to the same embodiment, nor is it a separate or alternative embodiment that is mutually exclusive with other embodiments. Those skilled in the art could understand, both explicitly and implicitly, that the embodiments described herein may be combined with other embodiments.

In the description of the embodiments of the present disclosure, orientation or positional relations indicated by technical terms such as “center”, “longitudinal”, “lateral”, “length”, “width”, “thickness”, “upper”, “lower”, “front”, “back”, “left”, “right”, “vertical”, “horizontal”, “top”, “bottom”, “inner”, “outer”, “clockwise”, “anticlockwise”, “axial”, “radial” and “circumferential” are based on orientation or positional relations as shown in the drawings, merely for facilitating the description of the embodiments of the present disclosure and simplifying the description, rather than indicating or implying that related devices or elements have to be in a particular orientation or configured and operated in a particular orientation, and therefore, they should not be construed as limitation to the embodiments of the present disclosure.

In the description of the present disclosure, unless otherwise specified and defined explicitly, technical terms such as “providing”, “mounting”, “joining”, “connecting” and “fixing” should be construed in a broad sense, for example, it may be a fixed connection, a detachable connection, or an integral connection; it may be a mechanical connection, or an electrical connection or a signal connection; it may be a direct connection, an indirect connection via an intermediary, or internal connection between two elements or interaction between two elements. For those ordinarily skilled in the art, specific meanings of the above-mentioned terms in the embodiments of the present disclosure could be understood according to specific circumstances.

In the embodiments of the present disclosure, the same reference numerals indicate the same components, and for the sake of brevity, detailed description of the same components is omitted in different embodiments. It should be understood that thicknesses, lengths and other dimensions of various components in the embodiments of the present disclosure, as well as overall thickness, length and other dimensions of an integrated device, as shown in the drawings, are illustrative only, and should not constitute any limitation to the present disclosure.

In one aspect, the present disclosure provides a preparation method for preparing an embedded three-dimensional fan-out package structure. The preparation method for preparing an embedded three-dimensional fan-out package structure may include the following steps: providing a multi-faceted pin chip, wherein pins of the multi-faceted pin chip may be distributed in different positions of multiple side surfaces of the multi-faceted pin chip; fabricating a chip module based on the multi-faceted pin chip, wherein pins of the chip module may be located in the same plane; bonding the chip module and an additional chip to a temporary carrier in a flip-mounting manner, so that the pins of the chip module and pins of the additional chip may be located in the same plane and be connected to the same surface of the temporary carrier; forming a plastic packaging layer on a side of the temporary carrier bonded with the chip module and the additional chip, so that the chip module and the additional chip may be embedded in the plastic packaging layer; removing the temporary carrier, so that the pins of the chip module and the pins of the additional chip may be exposed from a first surface of the plastic packaging layer, wherein a redistribution layer may be formed on the first surface of the plastic packaging layer, and wherein the redistribution layer may include a wiring dielectric layer adjacent to the plastic packaging layer, a protective dielectric layer provided on a side of the wiring dielectric layer facing away from the chip modules and the additional chips, as well as an electrically conductive wiring layer embedded in the wiring dielectric layer and the protective dielectric layer and electrically connected to the chip module and the additional chip, and wherein the electrically conductive wiring layer may include: lower pins respectively electrically connected to the pins of the chip module and the pins of the additional chip, interconnection lines connecting the pins of the chip module and the pins of the additional chip, first metal pillars respectively extending from the lower pins and the interconnection lines in a direction facing away from the chip module and the additional chip and electrically connected to corresponding lower pins and interconnection lines, as well as upper pins each formed at an end of the first metal pillars away from the chip module and the additional chip and electrically connected to the first metal pillars, and wherein electrically conductive solder balls and/or bumps may be formed on a side of the protective dielectric layer in the redistribution layer facing away from the chip module and the additional chip, and wherein the electrically conductive solder balls and/or bumps may pass through the protective dielectric layer to be electrically connected to the upper pins of the electrically conductive wiring layer.

In some optional embodiments, fabricating a chip module based on the multi-faceted pin chip may include: providing an insulating frame, wherein a first groove and a second groove extending through the insulating frame may be formed on the insulating frame; providing an electrically conductive layer structure provided with a supporting substrate at bottom, wherein a first bonding adhesive layer may be formed on top of the electrically conductive layer structure opposite to the supporting substrate; bonding the insulating frame formed with the first groove and the second groove onto a side of the first bonding adhesive layer opposite to the electrically conductive layer structure; removing parts of the first bonding adhesive layer exposed via the first groove and the second groove, so as to expose parts of the electrically conductive layer structure facing open ends of the first groove and the second groove, wherein a metal material layer may be formed on a surface of a part of the electrically conductive layer structure facing the open end of the first groove, and an electrically conductive adhesive layer may be formed on a side of the metal material layer opposite to the electrically conductive layer structure; and bonding the multi-faceted pin chip in the first groove through the electrically conductive adhesive layer, so that the pins on at least one side surface of the multi-faceted pin chip are electrically connected to the electrically conductive layer structure; and filling the second groove with a metal material so as to form second metal pillars electrically connected to the electrically conductive layer structure, and forming metal leads at ends of the second metal pillars opposite to the electrically conductive layer structure, so as to transfer (relayout) the pins of the multi-faceted pin chip to the same plane so that all pins of the chip module are located in the same plane.

In some optional embodiments, the preparation method for preparing an embedded three-dimensional fan-out package structure further may include: providing a heat dissipation frame after fabricating the chip module based on the multi-faceted pin chip; accommodating the chip module and the additional chip fixedly in the heat dissipation frame, so that the pins of the chip module and the pins of the additional chip are located in the same plane; bonding the chip module and the additional chip bonded in the heat dissipation frame to the temporary carrier in a flip-mounting manner, so that the pins of the chip module and the pins of the additional chip are connected to the same plane of the temporary carrier, while the heat dissipation frame is spaced apart from the temporary carrier; and forming the plastic packaging layer on a side of the temporary carrier bonded with the chip module and the additional chip, so that the heat dissipation frame is embedded together with the chip module and the additional chip in the plastic packaging layer.

In some optional embodiments, accommodating the chip module and the additional chip fixedly in the heat dissipation frame may include: forming a chip module accommodating groove and a chip accommodating groove, each being closed at bottom, on the same side of the heat dissipation frame, wherein a chip module bonding adhesive layer may be provided at the bottom of the chip module accommodating groove, and a chip bonding adhesive layer may be provided at the bottom of the chip accommodating groove; bonding the chip module in the chip module accommodating groove through the chip module bonding adhesive layer, and bonding the additional chip in the chip accommodating groove through the chip bonding adhesive layer, so that the pins of the chip module and the pins of the additional chip may respectively protrude from open ends of the chip module accommodating groove and the chip accommodating groove and be located in the same plane.

In some optional embodiments, the heat dissipation frame in the preparation method for preparing an embedded three-dimensional fan-out package structure may be a copper frame.

In some optional embodiments, fabricating a chip module based on the multi-faceted pin chip may include: providing an insulating frame, wherein a first groove extending through the insulating frame may be formed on the insulating frame; providing an electrically conductive layer structure provided with a supporting substrate at bottom; forming a first bonding adhesive layer on top of the electrically conductive layer structure opposite to the supporting substrate; bonding the insulating frame formed with the first groove to a side of the first bonding adhesive layer opposite to the electrically conductive layer structure, wherein a continuous metal material layer may be formed on a surface of a part of the first bonding adhesive layer facing an open end of the first groove and on a surface of a side wall of the first groove, and metal leads electrically connected to the metal material layer may be formed on a surface of the insulating frame surrounding the open end of the first groove, and wherein the metal leads are configured to transfer the pins of the multi-faceted pin chip to the same plane so that all pins of the chip module are located in the same plane; forming an electrically conductive adhesive layer on a surface of a part of the metal material layer facing the open end of the first groove; and bonding the multi-faceted pin chip in the first groove through the electrically conductive adhesive layer, so that the pins on at least one side surface of the multi-faceted pin chip may be electrically connected to the metal material layer.

In some optional embodiments, fabricating a chip module based on the multi-faceted pin chip may include: providing an electrically conductive layer structure provided with a supporting substrate at bottom; forming a first bonding adhesive layer on top of the electrically conductive layer structure opposite to the supporting substrate; forming an electrically conductive adhesive accommodating groove extending through the first bonding adhesive layer in the first bonding adhesive layer, so as to expose a part of the electrically conductive layer structure facing an open end of the electrically conductive adhesive accommodating groove; filling an electrically conductive adhesive in the electrically conductive adhesive accommodating groove so as to form an electrically conductive adhesive layer; and bonding the multi-faceted pin chip to the electrically conductive adhesive layer so as to form a chip stack, wherein pins on at least one side surface of the multi-faceted pin chip are electrically connected to the electrically conductive layer structure via the electrically conductive adhesive layer. Moreover, this preparation method may include: before forming the redistribution layer on the first surface of the plastic packaging layer, bonding the chip stack and the additional chip to the temporary carrier in a flip-mounting manner, so that pins of the chip stack located on a side opposite to the electrically conductive layer structure and the pins of the additional chip are located in the same plane and are connected to the same surface of the temporary carrier, wherein a plastic packaging layer may be formed on a side of the temporary carrier bonded with the chip stack and the additional chip, so that the chip stack and the additional chip may be embedded in the plastic packaging layer; removing the temporary carrier, so that the pins of the chip stack located on the side opposite to the electrically conductive layer structure and the pins of the additional chip may be exposed from the first surface of the plastic packaging layer; forming on the first surface of the plastic packaging layer communicating holes extending inwardly through the plastic packing layer and the first bonding adhesive layer located between the first surface and the electrically conductive layer structure of the chip stack around the chip stack, wherein a metal material may be filled in the communicating holes so as to form guide metal pillars electrically connected to the electrically conductive layer structure, and wherein the guide metal pillars transfer the pins of the multi-faceted pin chip electrically connected to the electrically conductive layer structure to be located in the same plane as the pins of the chip stack exposed from the first surface of the plastic packaging layer.

In some optional embodiments, forming the redistribution layer on the first surface of the plastic packaging layer may include that the lower pins and the interconnection lines may be formed from a metal material at positions on the first surface of the plastic packaging layer corresponding to the pins of the chip module and the pins of the additional chip exposed on the first surface; the wiring dielectric layer is formed, so that the wiring dielectric layer may cover the lower pins and the interconnection lines as well as the first surface; first through-holes are formed at positions of the wiring dielectric layer corresponding to the lower pins and the interconnection lines, so that the first through-holes may extend through the wiring dielectric layer up to the lower pins and the interconnection lines; the first through-holes are filled with a metal material to form the first metal pillars, so that the first metal pillars may be electrically connected to the lower pins and the interconnection lines; the upper pins are formed from a metal material at ends of the first metal pillars opposite to the plastic packaging layer, so that the upper pins are electrically connected to the first metal pillars and partially protrude above the wiring dielectric layer; the protective dielectric layer is formed, so that the protective dielectric layer may cover the upper pins and the wiring dielectric layer; and blind vias are formed at positions of the protective dielectric layer corresponding to the upper pins, so that the blind vias extend through the protective dielectric layer and make the upper pins exposed.

In some optional embodiments, the wiring dielectric layer and the protective dielectric layer in the preparation method for preparing an embedded three-dimensional fan-out package structure may be formed by spin coating or deposition.

In some optional embodiments, the electrically conductive solder balls in the preparation method for preparing an embedded three-dimensional fan-out package structure may be formed by solder balls prepared in advance or stencil printing and reflowing, and the bumps may be formed by evaporation or sputtering.

In some optional embodiments, the grooves, the through-holes, the communicating holes and/or the blind vias in the preparation method for preparing an embedded three-dimensional fan-out package structure may be formed by at least one of photolithography and chemical etching.

In some optional embodiments, the lower pins, the interconnection lines and/or the upper pins in the preparation method for preparing an embedded three-dimensional fan-out package structure may be formed from a metal material by electroplating.

In some optional embodiments, the metal material in the preparation method for preparing an embedded three-dimensional fan-out package structure may include at least one of copper, aluminum, silver or gold.

According to the preparation method for preparing an embedded three-dimensional fan-out package structure provided in the present disclosure, by pre-fabricating a separate chip module based on the multi-faceted pin chip, and making the pins of the fabricated chip module to be located in the same plane, heterogeneous integration packaging between the multi-faceted pin chip and the additional chip can be realized through the existing packaging process, without the need of additionally adding wire bonding equipment for leading out the pins of the multi-faceted pin chip located at different positions of multiple side surfaces, which reduces the wire bonding cost, while omitting the conventional manner of assisting surface packaging by wire bonding, thus the equipment cost and production cost can be reduced while meeting the need for the development of high-density advanced packaging.

The preparation method for preparing an embedded three-dimensional fan-out package structure and an embedded three-dimensional fan-out package structure prepared according to this preparation method are described in detail according to exemplary embodiments of the present disclosure with reference to the drawings.

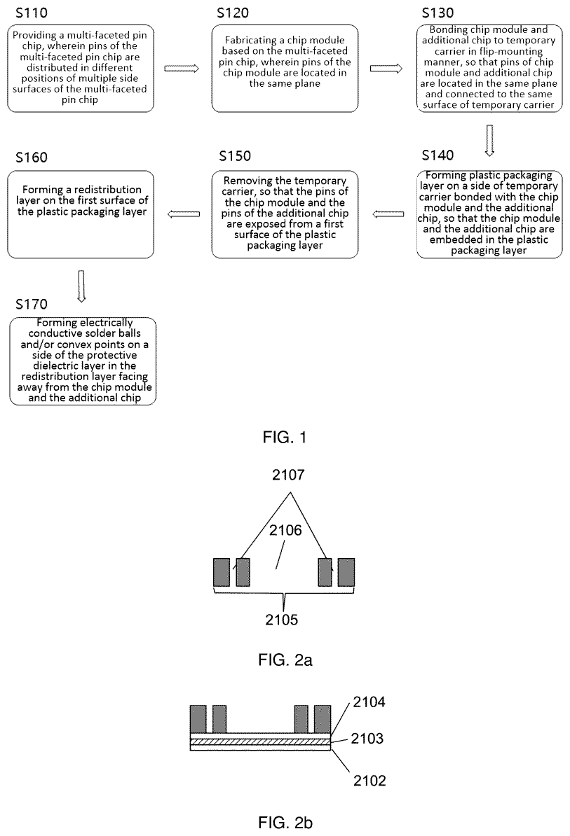

Reference is made to FIG. 1 first. FIG. 1 shows a schematic flowchart of a preparation method for preparing an embedded three-dimensional fan-out package structure according to an exemplary embodiment of the present disclosure.

According to the shown exemplary embodiment, the preparation method for preparing an embedded three-dimensional fan-out package structure may include the following steps:
step S110, providing a multi-faceted pin chip, wherein pins of the multi-faceted pin chip are distributed in different positions of multiple side surfaces of the multi-faceted pin chip;
step S120, fabricating a chip module based on the multi-faceted pin chip, so that pins of the chip module are located in the same plane;
step S130, bonding the chip module and an additional chip to a temporary carrier in a flip-mounting manner, so that the pins of the chip module and pins of the additional chip are located in the same plane and are connected to the same surface of the temporary carrier;
step S140, forming a plastic packaging layer on a side of the temporary carrier bonded with the chip module and the additional chip, so that the chip module and the additional chip are embedded in the plastic packaging layer;
step S150, removing the temporary carrier, so that the pins of the chip module and the pins of the additional chip are exposed from a first surface of the plastic packaging layer;
step S160, forming a redistribution layer on the first surface of the plastic packaging layer, wherein the redistribution layer may include a wiring dielectric layer adjacent to the plastic packaging layer, a protective dielectric layer provided on a side of the wiring dielectric layer facing away from the chip modules and the additional chips, as well as an electrically conductive wiring layer embedded in the wiring dielectric layer and the protective dielectric layer and electrically connected to the chip module and the additional chip, and wherein the electrically conductive wiring layer may include: lower pins respectively electrically connected to the pins of the chip module and the pins of the additional chip, interconnection lines connecting the pins of the chip module and the pins of the additional chip, first metal pillars respectively extending from the lower pins and the interconnection lines in a direction away from the chip module and the additional chip and electrically connected to corresponding lower pins and interconnection lines, as well as upper pins each formed at an end of the first metal pillars away from the chip module and the additional chip and electrically connected to the first metal pillars; and
step S170, forming electrically conductive solder balls and/or bumps on a side of the protective dielectric layer in the redistribution layer facing away from the chip module and the additional chip.

It should be indicated that, the phrasing “flip-mounting manner” herein refers to an operation of mounting input/output pins or pads of a chip by flipping them downwards in the flip-chip packaging technology (FC) which is well known in the art. Specific contents of this operation are not repeated in the documents of the present disclosure to avoid confusing the description of various embodiments of the present disclosure.

According to the preparation method for preparing an embedded three-dimensional fan-out package structure provided according to the above exemplary embodiment of the present disclosure, by pre-fabricating a separate chip module based on the multi-faceted pin chip, and making the pins of the fabricated chip module to be located in the same plane, heterogeneous integration packaging between the multi-faceted pin chip and the additional chip can be realized through the existing packaging process, without the need of additionally adding wire bonding equipment for leading out the pins of the multi-faceted pin chip located at different positions of multiple side surfaces, which reduces the wire bonding cost, while omitting the conventional manner of assisting surface packaging by wire bonding, thus meeting the need for development of high-density advanced packaging.

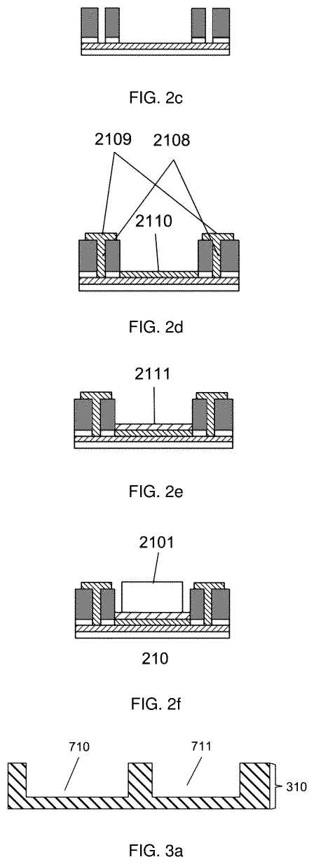

FIG. 2a to FIG. 2f show illustrative schematic diagrams of fabricating a chip module 210 based on a multi-faceted pin chip in the preparation method according to an exemplary embodiment of the present disclosure. With reference to FIG. 2a to FIG. 2f, according to the shown embodiment, fabricating the chip module 210 based on a multi-faceted pin chip may include the following steps: as shown in FIG. 2a, an insulating frame 2105 is provided and a first groove 2106 and a second groove 2107 extending through the insulating frame 2105 may be formed on the insulating frame 2105; as shown in FIG. 2b, an electrically conductive layer structure 2103 provided with a supporting substrate 2102 at bottom is provided, wherein a first bonding adhesive layer 2104 is formed on top of the electrically conductive layer structure 2103 opposite to the supporting substrate 2102, and then the insulating frame 2105 formed with the first groove 2106 and the second groove 2107 may be bonded onto a side of the first bonding adhesive layer 2104 opposite to the electrically conductive layer structure 2103; as shown in FIG. 2c, parts of the first bonding adhesive layer 2104 exposed via the first groove 2106 and the second groove 2107 are exposed, so as to expose parts of the electrically conductive layer structure 2103 facing open ends of the first groove 2106 and the second groove 2107; as shown in FIG. 2d, a metal material layer 2110 is formed on a surface of a part of the electrically conductive layer structure 2103 facing the open end of the first groove 2016, and the second groove 2107 is filled with a metal material so as to form second metal pillars 2108 electrically connected to the electrically conductive layer structure 2103, and metal leads 2109 are formed at ends of the second metal pillars 2108 opposite to the electrically conductive layer structure 2103, so as to transfer the pins of the multi-faceted pin chip 2101 to the same plane so that all pins of the chip module 210 are located in the same plane; as shown in FIG. 2e, an electrically conductive adhesive layer 2111 is formed on a side of the metal material layer 2110 opposite to the electrically conductive layer structure 2103; and as shown in FIG. 2f, the multi-faceted pin chip 2101 may be bonded in the first groove 2106 through the electrically conductive adhesive layer 2103, so that the pins on at least one side surface of the multi-faceted pin chip 2101 are electrically connected to the electrically conductive layer structure 2103.

It should be indicated that those skilled in the art could understand that the term “additional chip” used in the present disclosure may include, but is not limited to, chips. In some embodiments, the embedded additional chip also alternatively includes other electronic components for heterogeneous integration packaging, additional fan-out package structures having been packaged with additional electronic components, etc. It also should be indicated that, according to the embodiments of the present disclosure, the number and/or function of the “additional chip” embedded in the embedded three-dimensional fan-out package structure are not limited. For example, the embedded additional chip may be a single electronic component, and also may be two or more electronic components with the same or different functions. For example, when a plurality of electronic components are embedded in the embedded three-dimensional fan-out package structure, the plurality of electronic components may be the same or different in dimension, preparing process, function, and/or material according to specific applications.

In addition, those skilled in the art could understand that, in the above and following various embodiments disclosed in the present disclosure, the order of various steps and/or processes shown is merely for the purpose of facilitating the description, but should not be considered as limiting. Although the present disclosure has been described with reference to exemplary embodiments, it should be understood that the order of various steps and/or processes in the present disclosure is not limited to the specific embodiments described and shown herein in detail. Those skilled in the art could make various changes to the order of various steps and/or processes without departing from the scope defined by the claims of the present disclosure.

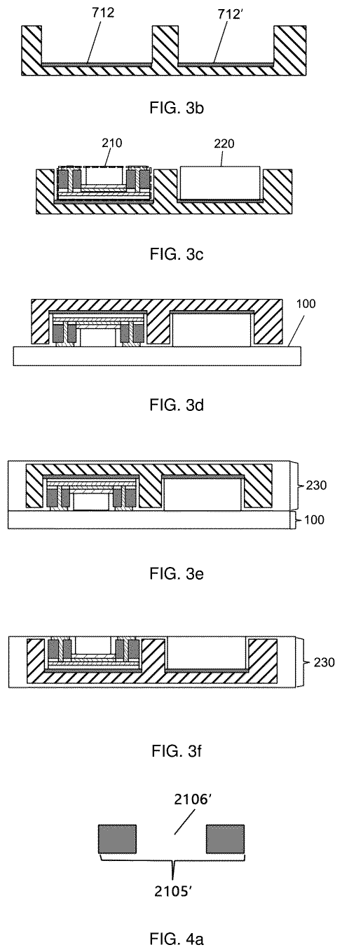

FIG. 3a to FIG. 3f show illustrative schematic diagrams of providing a heat dissipation frame and embedding the heat dissipation frame with the chip module and the additional chip in the plastic packaging layer in the preparation method according to an exemplary embodiment of the present disclosure. Specifically, in FIG. 3a to FIG. 3f, according to the shown embodiment, the preparation method for preparing an embedded three-dimensional fan-out package structure further includes providing a heat dissipation frame 310 after fabricating the chip module based on the multi-faceted pin chip as shown in FIG. 2a to FIG. 2f, and a detailed process thereof is as follows: as shown in FIG. 3a, forming a chip module accommodating groove 710 and a chip accommodating groove 711, each being closed at bottom, on the same side of the heat dissipation frame 310; as shown in FIG. 3b, providing a chip module bonding adhesive layer 712 at the bottom of the chip module accommodating groove 710, and providing a chip bonding adhesive layer 712′ at the bottom of the chip accommodating groove 711; as shown in FIG. 3c, bonding the chip module 210 in the chip module accommodating groove 710 through the chip module bonding adhesive layer 712, and bonding an additional chip 220 in the chip accommodating groove 711 through the chip bonding adhesive layer 712′, so that pins of the chip module 210 and pins of the additional chip 220 respectively protrude from open ends of the chip module accommodating groove 710 and the chip accommodating groove 711 and are located in the same plane; as shown in FIG. 3d, bonding the chip module 210 and the additional chip 220 accommodated in the heat dissipation frame 310 to a temporary carrier 100 in a flip-mounting manner, so that the pins of the chip module 210 and the pins of the additional chip 220 are connected to the same surface of the temporary carrier 100, and the heat dissipation frame 310 is spaced apart from the temporary carrier 100; as shown in FIG. 3e, forming a plastic packaging layer 230 on a side of the temporary carrier 100 bonded with the chip module 210 and the additional chip 220, so that the heat dissipation frame 310 is embedded in the plastic packaging layer 230 with the chip module 210 and the additional chip 220. In addition, as shown in FIG. 3f, the temporary carrier 100 subsequently may be removed so as to obtain a separate plastic packaging layer 230, so that subsequent packaging operations may be performed according to the embodiments of the present disclosure, for example, forming the redistribution layer on the first surface of the obtained plastic packaging layer 230; and forming the electrically conductive solder balls and/or bumps and the like on the side of the protective dielectric layer in the redistribution layer facing away from the chip module and the additional chip, thereby finally forming the embedded three-dimensional fan-out package structure according to an embodiment of the present disclosure.

The preparation method for preparing an embedded three-dimensional fan-out package structure provided according to embodiments of the present disclosure further may include embedding the heat dissipation frame in the plastic packaging layer, and therefore, in addition to the advantages of the embodiments as shown in FIG. 2a to FIG. 2f, there further may be an advantage of improving thermal conductivity of the plastic packaging layer, so that the heat dissipation efficiency of the whole package structure can be improved.

It should be indicated that the heat dissipation frame in the embodiments of the present disclosure may be a copper frame, but it is not limited to the copper frame. In some embodiments, the heat dissipation frame also may be made from other metals, or high-thermal-conductivity materials or composite materials.

In addition, according to the embodiments of the present disclosure, it may be understood that there may be more than one heat dissipation frame in the embodiments of the present disclosure, and those skilled in the art could reasonably design and combine the heat dissipation frames according to practical heat dissipation requirements.

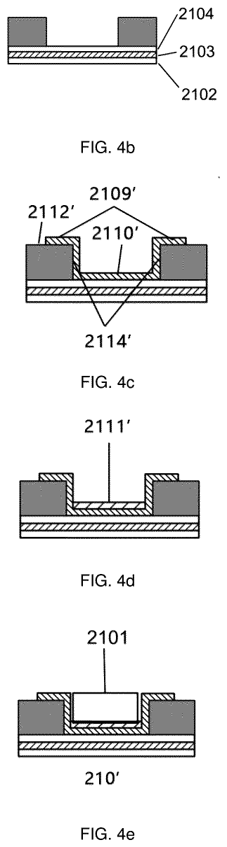

FIG. 4a to FIG. 4e are illustrative schematic diagrams showing fabrication of a chip module 210′ based on a multi-faceted pin chip in the preparation method according to an exemplary embodiment of the present disclosure. With reference to FIG. 4a to FIG. 4e, according to the shown embodiment, fabricating the chip module 210′ based on a multi-faceted pin chip may include the following steps: as shown in FIG. 4a, providing an insulating frame 2105′, and forming on the insulating frame 2105′ a first groove 2106′ extending through the insulating frame 2105′; as shown in FIG. 4b, providing an electrically conductive layer structure 2103 provided with a supporting substrate 2102 at bottom, wherein a first bonding adhesive layer 2104 is formed on top of the electrically conductive layer structure 2103 opposite to the supporting substrate 2102, and the insulating frame 2105′ formed with the first groove 2106′ is bonded onto a side of the first bonding adhesive layer 2104 opposite to the electrically conductive layer structure 2103; as shown in FIG. 4c, forming a continuous metal material layer 2110′ on a surface of a part of the first bonding adhesive layer 2104 facing an open end 2112′ of the first groove 2106′ and on a surface of a side wall 2114′ of the first groove 2106′, and forming metal leads 2109′ electrically connected to the metal material layer 2110′ on a surface of the insulating frame 2105′ surrounding the open end 2112′ of the first groove 2106′, wherein the metal leads 2109′ are configured to transfer the pins of a multi-faceted pin chip 2101 to the same plane so that all pins of chip module 210′ are located in the same plane; as shown in FIG. 4d, forming an electrically conductive adhesive layer 2111′ on a surface of a part of the metal material layer 2110′ facing the open end of the first groove 2106′; and as shown in FIG. 4e, bonding the multi-faceted pin chip 2101 in the first groove 2106′ through the electrically conductive adhesive layer 2111′, so that the pins on at least one side surface of the multi-faceted pin chip 2101 are electrically connected to the metal material layer 2110′.

Compared with the fabrication of a chip module based on a multi-faceted pin chip in the embodiment as shown in FIG. 2a to FIG. 2f, the fabrication of a chip module based on a multi-faceted pin chip according to the embodiment as shown in FIG. 4a to FIG. 4e of the present disclosure is mainly different in that interconnection lines fabricated are different. The fabrication of the interconnection lines in the fabrication of the chip module based on a multi-faceted pin chip as shown in FIG. 4a to FIG. 4e neither needs formation of a second groove (for example, the second groove 2107 as shown in FIG. 2a) on the insulating frame 2105′, nor needs to remove a bonding adhesive layer (for example, the first bonding adhesive layer 2104 as shown in FIG. 2b) at bottom of this groove, thus, in addition to the advantages of the embodiment as shown in FIG. 2a to FIG. 2f, it also has simpler fabrication steps, so that the fabrication process of the interconnection lines having the chip module as shown in FIG. 4a to FIG. 4e is simpler.

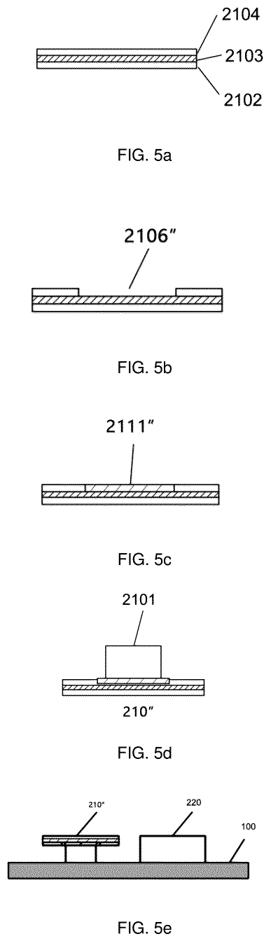

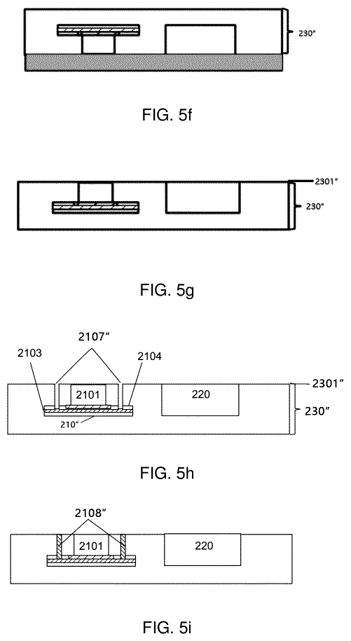

FIG. 5a to FIG. 5i are illustrative schematic diagrams showing fabrication of a chip module based on a multi-faceted pin chip in the preparation method according to an exemplary embodiment of the present disclosure. With reference to FIG. 5a to FIG. 5i, according to the shown embodiment, fabricating a chip module based on a multi-faceted pin chip may include: as shown in FIG. 5a, providing an electrically conductive layer structure 2103 provided with a supporting substrate 2102 at bottom, and forming a first bonding adhesive layer 2104 on top of the electrically conductive layer structure 2103 opposite to the supporting substrate 2102; as shown in FIG. 5b, forming an electrically conductive adhesive accommodating groove 2106″ extending through the first bonding adhesive layer 2104 in the first bonding adhesive layer 2104, so as to expose a part of the electrically conductive layer structure 2103 facing an open end of the electrically conductive adhesive accommodating groove 2106″; as shown in FIG. 5c, filling an electrically conductive adhesive in the electrically conductive adhesive accommodating groove 2106″ so as to form an electrically conductive adhesive layer 2111″; and as shown in FIG. 5d, bonding a multi-faceted pin chip 2101 to the electrically conductive adhesive layer 2111″, so as to form a chip stack 210″, wherein pins on at least one side surface of the multi-faceted pin chip 2101 are electrically connected to the electrically conductive layer structure 2103 via the electrically conductive adhesive layer 2111″. According to the shown embodiment, the preparation method further includes: before forming the redistribution layer on the first surface of the plastic packaging layer, as shown in FIG. 5e, bonding the chip stack 210″ and an additional chip 220 to a temporary carrier 100 in a flip-mounting manner, so that pins of the chip stack 210″ located on a side opposite to the electrically conductive layer structure 2103 and pins of the additional chip 220 are located in the same plane and are connected to the same surface of the temporary carrier 100; as shown in FIG. 5f, forming a plastic packaging layer 230″ on a side of the temporary carrier 100 bonded with the chip stack 210″ and the additional chip 220, so that the chip stack 210″ and the additional chip 220 are embedded in the plastic packaging layer 230″; as shown in FIG. 5g, removing the temporary carrier 100, so that the pins of the chip stack 210″ located on a side opposite to the electrically conductive layer structure 2103 and the pins of the additional chip 220 are exposed from the first surface 2301″ of the plastic packaging layer 230″; as shown in FIG. 5h, forming on the first surface 2301″ of the plastic packaging layer 230″ communicating holes 2107″ extending inwardly through the plastic packing layer 230″ and the first bonding adhesive layer located between the first surface 2301″ and the electrically conductive layer structure 2103 of the chip stack 210″ around the chip stack 210″; and as shown in FIG. 5i, filling a metal material in the communicating holes 2107″ so as to form guide metal pillars 2108″ electrically connected to the electrically conductive layer structure 2103, wherein the guide metal pillars 2108″ transfer the pins of the multi-faceted pin chip 2101 electrically connected to the electrically conductive layer structure 2103 to be located in the same plane as the pins of the chip stack 210″ exposed from the first surface 2301″ of the plastic packaging layer 230″.

Compared with the fabrication of a chip module based on a multi-faceted pin chip in the embodiment as shown in FIG. 2a to FIG. 2f, the fabrication of a chip module based on a multi-faceted pin chip according to the embodiment as shown in FIG. 5a to FIG. 5i of the present disclosure is mainly different in that interconnection lines fabricated are different. The chip module fabricated based on a multi-faceted pin chip as shown in FIG. 5a to FIG. 5i does not need to use an insulating frame (for example, the insulating frame 2105 as shown in FIG. 2a to FIG. 2f), but adopts a manner of pre-fabricating a chip stack, further simplifying the fabricating process. In addition, interconnection lines of the multi-faceted pin chip 2101 are fabricated on a plastic packaging material of the plastic packaging layer 230″, and therefore, in addition to the advantages of the embodiment as shown in FIG. 2a to FIG. 2f, as the process of fabricating the interconnection lines of the chip module is simpler, the process of the preparation method of the three-dimensional fan-out package structure is simpler.

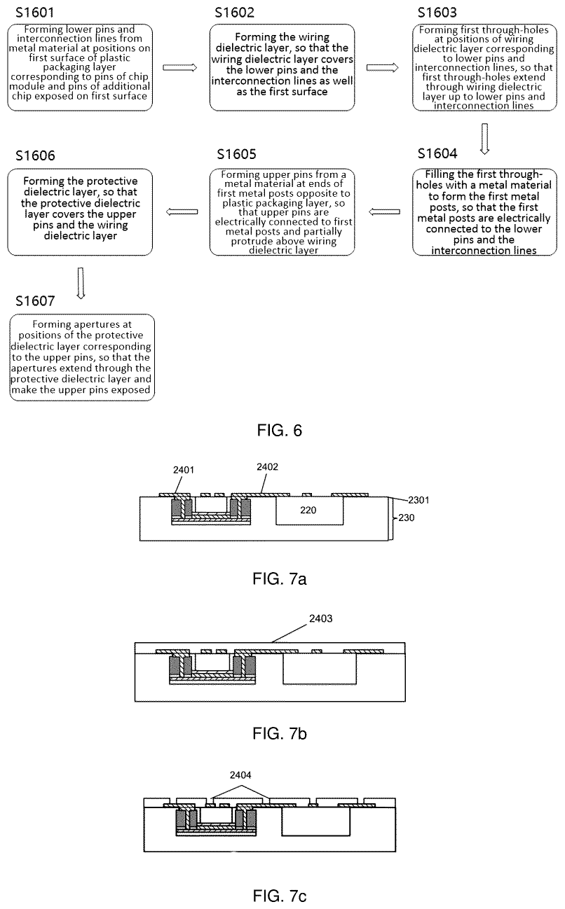

FIG. 6 shows a schematic flowchart of forming the redistribution layer on the first surface of the plastic packaging layer (step S160) in the preparation method as shown in FIG. 1. As shown in FIG. 6, according to an exemplary embodiment of the present disclosure, forming the redistribution layer on the first surface of the plastic packaging layer may include the following steps:
step S1601, forming the lower pins and the interconnection lines from a metal material at positions on the first surface of the plastic packaging layer corresponding to the pins of the chip module and the pins of the additional chip exposed on the first surface;
step S1602, forming the wiring dielectric layer, so that the wiring dielectric layer covers the lower pins and the interconnection lines as well as the first surface;
step S1603, forming first through-holes at positions of the wiring dielectric layer corresponding to the lower pins and the interconnection lines, so that the first through-holes extend through the wiring dielectric layer up to the lower pins and the interconnection lines;
step S1604, filling the first through-holes with a metal material to form the first metal pillars, so that the first metal pillars are electrically connected to the lower pins and the interconnection lines;
step S1605, forming the upper pins from a metal material at ends of the first metal pillars opposite to the plastic packaging layer, so that the upper pins are electrically connected to the first metal pillars and partially protrude above the wiring dielectric layer;
step S1606, forming the protective dielectric layer, so that the protective dielectric layer covers the upper pins and the wiring dielectric layer; and
step S1607, forming blind vias at positions of the protective dielectric layer corresponding to the upper pins, so that the blind vias extend through the protective dielectric layer and make the upper pins exposed.

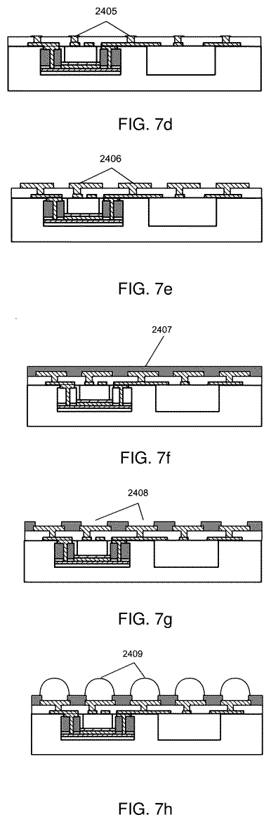

FIG. 7a to FIG. 7h are illustrative schematic diagrams corresponding to various steps of forming the redistribution layer on the first surface of the plastic packaging layer as shown in FIG. 6 according to the present disclosure. With reference to FIG. 7a to FIG. 7h, according to an embodiment of the present disclosure, forming a redistribution layer 240 on a first surface 2301 of a plastic packaging layer 230 may include: as shown in FIG. 7a, forming lower pins 2401 and interconnection lines 2402 from a metal material at positions on the first surface 2301 of the plastic packaging layer 230 corresponding to pins of a chip module 210 and pins of an additional chip 220 exposed on the first surface 2301; as shown in FIG. 7b, forming a wiring dielectric layer 2403, so that the wiring dielectric layer 2403 covers the lower pins 2401 and the interconnection lines 2402 as well as the first surface 2301; as shown in FIG. 7c, forming first through-holes 2404 at positions of the wiring dielectric layer 2403 corresponding to the lower pins 2401 and the interconnection lines 2402, so that the first through-holes 2404 extend through the wiring dielectric layer 2403 up to the lower pins 2401 and the interconnection lines 2402; as shown in FIG. 7d, filling the first through-holes 2404 with a metal material to form first metal pillars 2405, so that the first metal pillars 2405 are electrically connected to the lower pins 2401 and the interconnection lines 2402; as shown in FIG. 7e, forming upper pins 2406 from a metal material at ends of the first metal pillars 2405 opposite to the plastic packaging layer 230, so that the upper pins 2406 are electrically connected to the first metal pillars 2405 and partially protrude above the wiring dielectric layer 2403; as shown in FIG. 7f, forming a protective dielectric layer 2407, so that the protective dielectric layer 2407 covers the upper pins 2406 and the wiring dielectric layer 2403; and as shown in FIG. 7g, forming blind vias 2408 at positions of the protective dielectric layer 2407 corresponding to the upper pins 2406, so that the blind vias 2408 extend through the protective dielectric layer 2407 and make the upper pins 2406 exposed. In addition, as shown in FIG. 7h, it further shows an illustrative schematic diagram of subsequently forming electrically conductive solder balls and/or bumps (not shown) on a side of the protective dielectric layer 2407 in the redistribution layer 240 facing away from the chip module 210 and the additional chip 220, wherein the electrically conductive solder balls 2409 pass through the protective dielectric layer 2407 to be electrically connected to the upper pins 2406 of the electrically conductive wiring layer.

In addition, the embodiment in FIG. 7h shows the electrically conductive solder balls 2409 at the blind vias 2408. It should be indicated that, optionally, the electrically conductive solder balls 2409 in the embodiment in FIG. 7h may be bumps.

The present disclosure provides an embedded three-dimensional fan-out package structure prepared according to the above preparation method. The embedded three-dimensional fan-out package structure according to the present disclosure may include: a plastic packaging layer, wherein the plastic packaging layer may include a first surface and a second surface opposite to the first surface; a chip module and an additional chip embedded in the first surface of the plastic packaging layer, wherein the chip module may include multi-faceted pin chips, the multi-faceted pin chips may have pins distributed in different positions of multiple side surfaces, the pins of the multi-faceted pin chips may be transferred into the same plane by guide metal pillars, so that the pins of the chip modules and pins of the additional chips are located in the same plane as the first surface of the plastic packaging layer; a redistribution layer, wherein the redistribution layer may be provided on the first surface of the plastic packaging layer, and the redistribution layer may include a wiring dielectric layer adjacent to the plastic packaging layer, a protective dielectric layer provided on a side of the wiring dielectric layer facing away from the chip modules and the additional chips, and an electrically conductive wiring layer embedded in the wiring dielectric layer and the protective dielectric layer and electrically connected to the chip module and the additional chip, and wherein the electrically conductive wiring layer may include: lower pins respectively electrically connected to the pins of the chip module and the pins of the additional chip, interconnection lines connecting the pins of the chip module and the pins of the additional chip, first metal pillars respectively extending from the lower pins and the interconnection lines in a direction facing away from the chip module and the additional chip and electrically connected to corresponding lower pins and the interconnection lines, as well as upper pins each formed at an end of the first metal pillars away from the chip module and the additional chip and electrically connected to the first metal pillars; and electrically conductive solder balls and/or bumps, wherein the electrically conductive solder balls and/or the bumps may be provided on a side of the protective dielectric layer in the redistribution layer facing away from the chip module and the additional chip and pass through the protective dielectric layer to be electrically connected to the upper pins of the electrically conductive wiring layer.

In some optional embodiments, the chip module may include: an electrically conductive layer structure provided with a supporting substrate at bottom; a first bonding adhesive layer formed on top of the electrically conductive layer structure opposite to the supporting substrate; an insulating frame bonded onto a side of the first bonding adhesive layer opposite to the electrically conductive layer structure, wherein the insulating frame may be formed with a first groove and a second groove penetrating the insulating frame, and a first bonding adhesive layer through-hole and a second bonding adhesive layer through-hole penetrating the first bonding adhesive layer may be respectively formed in parts of the first bonding adhesive layer facing open ends of the first groove and the second groove; a metal material layer filled in the first bonding adhesive layer through-hole and electrically connected to the electrically conductive layer structure; an electrically conductive adhesive layer formed on a side of the metal material layer opposite to the electrically conductive layer structure; the multi-faceted pin chip bonded in the first groove through the electrically conductive adhesive layer, wherein pins on at least one side surface of the multi-faceted pin chip may be electrically connected to the electrically conductive layer structure via the electrically conductive adhesive layer and the metal material layer; second metal pillars filled in the second groove of the insulating frame and the second bonding adhesive layer through-hole, as well as metal leads formed at ends of the second metal pillars opposite to the electrically conductive layer structure, for guiding the pins of the multi-faceted pin chip to the same plane, so that all the pins of the chip module are located in the same plane.

In some optional embodiments, the embedded three-dimensional fan-out package structure further may include a heat dissipation frame, wherein the heat dissipation frame may be embedded together with the chip module and the additional chip in the plastic packaging layer. In the above, the heat dissipation frame includes a chip module accommodating groove and a chip accommodating groove, each being closed at bottom, formed on the same side of the heat dissipation frame. A chip module bonding adhesive layer may be provided at the bottom of the chip module accommodating groove, and a chip bonding adhesive layer may be provided at the bottom of the chip accommodating groove. The chip module is bonded in the chip module accommodating groove through the chip module bonding adhesive layer, and the additional chip is bonded in the chip accommodating groove through the chip bonding adhesive layer. The pins of the chip module and the pins of the additional chip may respectively protrude from open ends of the chip module accommodating groove and the chip accommodating groove and be located in the same plane.

In some optional embodiments, the heat dissipation frame in the embedded three-dimensional fan-out package structure may be a copper frame.

In some optional embodiments, the chip module may include an electrically conductive layer structure provided with a supporting substrate at bottom; a first bonding adhesive layer formed on top of the electrically conductive layer structure opposite to the supporting substrate; an insulating frame bonded onto a side of the first bonding adhesive layer opposite to the electrically conductive layer structure, wherein the insulating frame may be formed with a first groove penetrating the insulating frame; a continuous metal material layer formed on a surface of a part of the first bonding adhesive layer facing an open end of the first groove and on a surface of a side wall of the first groove, and metal leads formed on a surface of the insulating frame surrounding the open end of the first groove and electrically connected to the metal material layer; an electrically conductive adhesive layer formed on a surface of a part of the metal material layer facing the open end of the first groove; and the multi-faceted pin chip, wherein the multi-faceted pin chip may be bonded in the first groove through the electrically conductive adhesive layer, so that the pins on at least one side surface of the multi-faceted pin chip are electrically connected to the metal material layer.

In some optional embodiments, the chip module may include: a chip stack, wherein the chip stack may include: an electrically conductive layer structure provided with a supporting substrate at bottom; a first bonding adhesive layer formed on top of the electrically conductive layer structure opposite to the supporting substrate, wherein an electrically conductive adhesive accommodating groove penetrating the first bonding adhesive layer may be formed in the first bonding adhesive layer; an electrically conductive adhesive layer formed in the electrically conductive adhesive accommodating groove; and the multi-faceted pin chip, wherein the multi-faceted pin chip may be bonded onto the electrically conductive layer structure through the electrically conductive adhesive layer, so that the pins on at least one side surface of the multi-faceted pin chip may be electrically connected to the electrically conductive layer structure, and the pins located on a side of the multi-faceted pin chip opposite to the electrically conductive layer structure may be exposed from a first surface of the plastic packaging layer and located in the same plane as the first surface; guide metal pillars provided around the chip stack, wherein the guide metal pillars transfer the pins of the multi-faceted pin chip electrically connected to the electrically conductive layer structure to be located in the same plane as the pins of the chip stack exposed from the first surface of the plastic packaging layer, and wherein the guide metal pillars extend from the electrically conductive layer structure and pass through the first bonding adhesive layer through-holes formed in the first bonding adhesive layer as well as the plastic packaging layer between the first surface and the electrically conductive layer structure.

In some optional embodiments, the metal material in the embedded three-dimensional fan-out package structure may include at least one of copper, aluminum, silver or gold.

The embedded three-dimensional fan-out package structure prepared according to the preparation method provided in the embodiments of the present disclosure has a higher performance, a lower delay, a smaller size, a lighter weight, lower power consumption required for each function and lower cost.

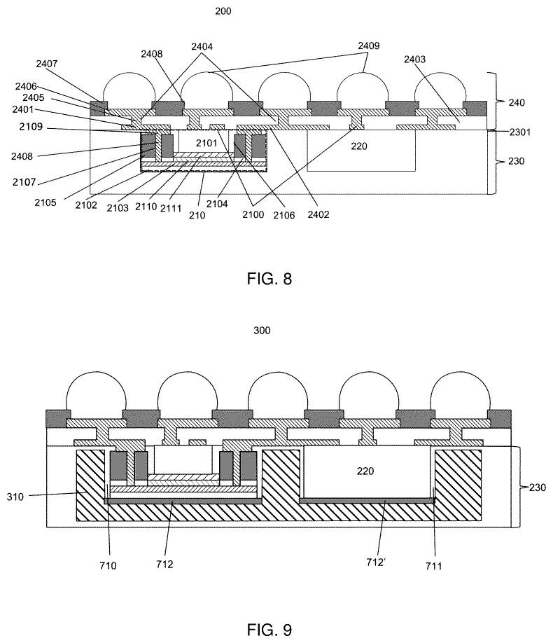

The embedded three-dimensional fan-out package structure prepared according to the preceding preparation method of the present disclosure is described below with reference to FIG. 8 to FIG. 11. FIG. 8 to FIG. 11 are schematic sectional diagrams of embedded three-dimensional fan-out package structures including chip modules fabricated according to different exemplary embodiments of fabricating a chip module based on a multi-faceted pin chip according to the present disclosure.

FIG. 8 shows a schematic sectional diagram of an embedded three-dimensional fan-out package structure 200 according to an exemplary embodiment of the present disclosure, wherein the embedded three-dimensional fan-out package structure 200 includes the chip module fabricated through steps as shown in FIG. 2a to FIG. 2f. As shown in FIG. 8, the embedded three-dimensional fan-out package structure 200 may include: a plastic packaging layer 230, wherein the plastic packaging layer 230 may include a first surface 2301 and a second surface opposite to the first surface; a chip module 210 and an additional chip 220 embedded in the first surface 2301 of the plastic packaging layer 230, wherein the chip module 210 may include a multi-faceted pin chip 2101, the multi-faceted pin chip 2101 may have pins distributed in different positions of multiple side surfaces, and the pins of the multi-faceted pin chip 2101 may be transferred into the same plane by metal leads 2109, so that the pins of the chip module 210 and the pins of the additional chip 220 are located in the same plane as the first surface 2301 of the plastic packaging layer 230; a redistribution layer 240, wherein the redistribution layer 240 may be provided on the first surface 2301 of the plastic packaging layer 230, the redistribution layer 240 may include a wiring dielectric layer 2403 adjacent to the plastic packaging layer 230, a protective dielectric layer 2407 provided on a side of the wiring dielectric layer 2403 facing away from the chip module 210 and the additional chip 220, and an electrically conductive wiring layer embedded in the wiring dielectric layer 2403 and the protective dielectric layer 2407 and electrically connected to the chip module 210 and the additional chip 220, and wherein the electrically conductive wiring layer may include: lower pins 2401 respectively electrically connected to the pins of the chip module 210 and the pins of the additional chip 220, interconnection lines 2402 connecting the pins of the chip module 210 and the pins of the additional chip 220, first metal pillars 2405 respectively extending from the lower pins 2401 and the interconnection lines 2402 in a direction facing away from the chip module 210 and the additional chip 220 and electrically connected to corresponding lower pins 2401 and interconnection lines 2402, and upper pins 2406 each formed at an end of the first metal pillars 2405 away from the chip module 210 and the additional chip 220 and electrically connected to the first metal pillars 2405; and electrically conductive solder balls 2409 and/or bumps (not shown), wherein the electrically conductive solder balls 2409 and/or the bumps may be provided on a side of the protective dielectric layer 2407 in the redistribution layer 240 facing away from the chip module 210 and the additional chip 220 and pass through the protective dielectric layer 2407 to be electrically connected to the upper pins 2406 of the electrically conductive wiring layer. Moreover, in the above, the chip module 210 may include: an electrically conductive layer structure 2103 provided with a supporting substrate 2102 at bottom; a first bonding adhesive layer 2104 formed on top of the electrically conductive layer structure 2103 opposite to the supporting substrate 2102; and an insulating frame 2105 bonded onto a side of the first bonding adhesive layer 2104 opposite to the electrically conductive layer structure 2103, wherein the insulating frame 2105 may be formed with a first groove 2106 and a second groove 2107 penetrating the insulating frame 2105, and a first bonding adhesive layer through-hole and a second bonding adhesive layer through-hole penetrating the first bonding adhesive layer 2103 may be respectively formed in parts of the first bonding adhesive layer 2103 facing open ends of the first groove 2106 and the second groove 2107; a metal material layer 2110 filled in the first bonding adhesive layer through-hole and electrically connected to the electrically conductive layer structure 2103; an electrically conductive adhesive layer 2111 formed on a side of the metal material layer 2110 opposite to the electrically conductive layer structure 2103; a multi-faceted pin chip 2101 bonded in the first groove 2106 through the electrically conductive adhesive layer 2111, wherein the pins on at least one side surface of the multi-faceted pin chip 2101 may be electrically connected to the electrically conductive layer structure 2103 via the electrically conductive adhesive layer 2110 and the metal material layer 2111; second metal pillars 2108 filled in the second groove 2107 of the insulating frame 2105 and the second bonding adhesive layer through-hole, as well as metal leads 2109 formed at ends of the second metal pillars 2108 opposite to the electrically conductive layer structure 2103, for guiding the pins of the multi-faceted pin chip 2101 to the same plane, so that all the pins of the chip module 210 are located in the same plane.

FIG. 9 shows a schematic sectional diagram of an embedded three-dimensional fan-out package structure 300 according to an embodiment of the present disclosure. The embedded three-dimensional fan-out package structure 300 includes a plastic packaging layer structure obtained through the steps as shown in FIG. 3a to FIG. 3f, wherein the heat dissipation frame is embedded in the plastic packaging layer with the chip module fabricated through the steps as shown in FIG. 2a to FIG. 2f and an additional chip. The embedded three-dimensional fan-out package structure 300 as shown in FIG. 9 is mainly different from the embedded three-dimensional fan-out package structure 200 as shown in FIG. 8 in that a heat dissipation frame 310 is further provided, wherein the heat dissipation frame 310 is embedded in the plastic packaging layer 230 with a chip module 210 and an additional chip 220. Therefore, for ease of description, the same parts of the embedded three-dimensional fan-out package structure 300 as shown in FIG. 9 as those of the embedded three-dimensional fan-out package structure 200 as shown in FIG. 8 are not repeated herein again, and reference may be specifically made to corresponding contents and relevant description as shown in FIG. 8.

As shown in FIG. 9, the embedded three-dimensional fan-out package structure 300 further may include a heat dissipation frame 310, wherein the heat dissipation frame 310 is embedded together with the chip module 210 and the additional chip 220 in the plastic packaging layer 230. In the above, the heat dissipation frame 310 includes a chip module accommodating groove 710 and a chip accommodating groove 711, each being closed at bottom, formed on the same side of the heat dissipation frame 310. A chip module bonding adhesive layer 712 is provided at the bottom of the chip module accommodating groove 710, and a chip bonding adhesive layer 712′ is provided at the bottom of the chip accommodating groove 711. The chip module is bonded in the chip module accommodating groove 710 through the chip module bonding adhesive layer 712, and the additional chip is bonded in the chip accommodating groove 711 through the chip bonding adhesive layer 712′. The pins of the chip module and the pins of the additional chip respectively protrude from open ends of the chip module accommodating groove 710 and the chip accommodating groove 711 and are located in the same plane.

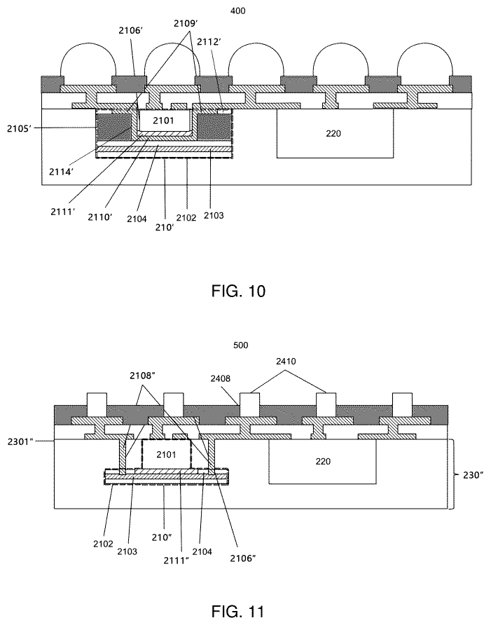

With reference to FIG. 10, FIG. 10 shows a schematic sectional diagram of an embedded three-dimensional fan-out package structure 400 according to an embodiment of the present disclosure. The embedded three-dimensional fan-out package structure 400 includes the chip module fabricated through the steps as shown in FIG. 4a to FIG. 4e. It should be indicated that the embedded three-dimensional fan-out package structure 400 in the embodiment as shown in FIG. 10 is mainly different from the embedded three-dimensional fan-out package structure 200 as shown in FIG. 8 in that: the chip module 210′ in FIG. 10 has a structure different than that of the chip module in FIG. 8, wherein the interconnection lines fabricated in the chip module are different, that is, in the embodiment as shown in FIG. 10, the chip module 410 does not need to form the interconnection lines by fabricating a second groove (for example, the second groove 2107 as shown in FIG. 2a) on the insulating frame 2105 of the chip module 210 as shown in FIG. 8. Therefore, for ease of description, the same parts of the embedded three-dimensional fan-out package structure 400 as shown in FIG. 10 as those of the embedded three-dimensional fan-out package structure 200 as shown in FIG. 8 are not repeated herein, and reference may be specifically made to corresponding contents and relevant description as shown in FIG. 8.

As shown in FIG. 10, the chip module 410 may include: an electrically conductive layer structure 2103 provided with a supporting substrate 2102 at bottom; a first bonding adhesive layer 2104 formed on top of the electrically conductive layer structure 2103 opposite to the supporting substrate 2102; an insulating frame 2105′ bonded onto a side of the first bonding adhesive layer 2104 opposite to the electrically conductive layer structure 2103, wherein the insulating frame 2105′ may be formed with a first groove 2106′ penetrating the insulating frame 2105′; a continuous metal material layer 2110′ formed on a surface of a part of the first bonding adhesive layer 2104 facing an open end 2112′ of the first groove 2106′ and on a surface of a side wall 2114′ of the first groove 2106′, and metal leads 2109′ formed on a surface of the insulating frame 2105′ surrounding the open end 2112′ of the first groove 2106′ and electrically connected to the metal material layer 2110′; an electrically conductive adhesive layer 2111′ formed on a surface of a part of the metal material layer 2110′ facing the open end 2112′ of the first groove; as well as a multi-faceted pin chip 2101, wherein the multi-faceted pin chip 2101 may be bonded in the first groove 2106′ through the electrically conductive adhesive layer 2111′, so that the pins on at least one side surface of the multi-faceted pin chip 2101 are electrically connected to the metal material layer 2110′.

With reference to FIG. 11, FIG. 11 shows a schematic sectional diagram of an embedded three-dimensional fan-out package structure 500 according to a further embodiment of the present disclosure, wherein the embedded three-dimensional fan-out package structure 500 includes the plastic packaging layer fabricated through the steps as shown in FIG. 5a to FIG. 5i. It should be indicated that the embedded three-dimensional fan-out package structure 500 in the embodiment as shown in FIG. 11 is different from the embedded three-dimensional fan-out package structure 200 as shown in FIG. 8 in that an arrangement structure of the chip stack and the additional chip embedded in the plastic packaging layer in the plastic packaging layer shown in FIG. 11 is different from an arrangement structure of the chip module 210 and the additional chip embedded in the plastic packaging layer in the plastic packaging layer shown in FIG. 8, and particularly, the interconnection lines fabricated in the chip module are different. In the embodiment as shown in FIG. 11, the interconnection lines of the chip stack 210″ (the chip module) do not need to be formed in an insulating frame (e.g., the insulating frame 2105 as shown in FIG. 8), but in the plastic packaging material of the plastic packaging layer 230″ as shown in FIG. 11. Besides, there is also a difference that bumps 2410 are formed in FIG. 11 to replace the electrically conductive solder balls 2409 in FIG. 8. Therefore, for ease of description, the same parts of the embedded three-dimensional fan-out package structure 500 shown in FIG. 11 as those of the structure 200 shown in FIG. 8 are not repeated herein again, and reference may be specifically made to corresponding contents and relevant description as shown in FIG. 8.

As shown in FIG. 11, the chip module may include: the chip stack 210″, wherein the chip stack 210″ may include the electrically conductive layer structure 2103 provided with the supporting substrate 2102 at the bottom; the first bonding adhesive layer 2104 formed on the top of the electrically conductive layer structure 2103 opposite to the supporting substrate 2102, wherein the electrically conductive adhesive accommodating groove 2106″ penetrating the first bonding adhesive layer 2104 may be formed in the first bonding adhesive layer 2104; the electrically conductive adhesive layer 2111″ formed in the electrically conductive adhesive accommodating groove 2106″; as well as the multi-faceted pin chip 2101, wherein the multi-faceted pin chip 2101 may be bonded onto the electrically conductive layer structure 2103 through the electrically conductive adhesive layer 2111″, so that the pins on at least one side surface of the multi-faceted pin chip 2101 may be electrically connected to the electrically conductive layer structure 2103, and the pins of the multi-faceted pin chip 2101 located on the side opposite to the electrically conductive layer structure 2103 may be exposed from the first surface 2301″ of the plastic packaging layer 230″ and located in the same plane as the first surface 2301″; the guide metal pillars 2108″ provided around the chip stack 210″, configured to transfer the pins of the multi-faceted pin chip 2101 electrically connected to the electrically conductive layer structure 2103 to be located in the same plane as the pins of the chip stack 210″ exposed from the first surface 2301″ of the plastic packaging layer 230″, wherein the guide metal pillars 2108″ extend from the electrically conductive layer structure 2103 and pass through the first bonding adhesive layer through-holes formed in the first bonding adhesive layer 2104 as well as the plastic packaging layer between the first surface 2301″ and the electrically conductive layer structure 2103.

In the above embodiments of the present disclosure, optionally, metal leads (not shown in FIG. 11) further may be formed at ends of the guide metal pillars 2108″ provided around the chip stack 210″ opposite to the electrically conductive layer structure 2103, wherein the metal leads are electrically connected to the guide metal pillars 2108″, so as to transfer the pins of the multi-faceted pin chip 2101 electrically connected to the electrically conductive layer structure 2103 to be located in the same plane as the pins of the chip stack 210″ exposed from the first surface 2301″ of the plastic packaging layer 230″.

It should be indicated that in some embodiments shown in the present disclosure, the process of forming the electrically conductive solder balls may be alternatively provided as a process of forming the bumps; and the process of forming the bumps also may be alternatively provided as the process of forming the electrically conductive solder balls.

It should be indicated that the technologies or processes of forming the first through-holes, the blind vias, the first groove, the second groove, the bonding adhesive layer through-holes, the communicating holes, the chip module accommodating groove and the chip accommodating groove are non-limiting in the present disclosure. In some embodiments according to the present disclosure, at least one of photolithography and chemical etching may be used to form the first through-holes, the blind vias, the first groove, the second groove, the bonding adhesive layer through-holes, the communicating holes, the chip module accommodating groove and the chip accommodating groove. However, the methods of forming the grooves, the blind vias or the holes are not limited thereto, but may be any method known in the art.

The technologies or processes of filling the first through-holes, the first groove, the second groove, the bonding adhesive layer through-holes and the communicating holes are non-limiting in the present disclosure. In some embodiments according to the present disclosure, the lower pins, the interconnection lines and/or the upper pines may be formed from a metal material by electroplating. However, the methods of forming the upper/lower pins and the interconnection lines are not limited thereto, but may be any method known in the art.

Additionally, it should be indicated that the technologies or processes of forming the wiring dielectric layer and the protective dielectric layer are non-limiting in the present disclosure. In some embodiments according to the present disclosure, the wiring dielectric layer and the protective dielectric layer may be formed by spin coating or deposition. However, the methods of forming the wiring dielectric layer and the protective dielectric layer are not limited thereto, but may be any method known in the art.

Besides, the technologies or processes of forming the electrically conductive solder balls or forming the bumps are non-limiting in the present disclosure. In some embodiments according to the present disclosure, the electrically conductive solder balls may be formed by ball mounting/stencil printing; and the bumps may be formed by evaporation or sputtering. However, the methods of forming the electrically conductive solder balls or the bumps are not limited thereto, but may be any method known in the art.

It can be understood that choices of the metal material are non-limiting in the present disclosure. In some embodiments according to the present disclosure, the metal material may include at least one of copper, aluminum, silver, or gold.

Features mentioned and/or shown in the description of the exemplary embodiments of the present disclosure in the above may be incorporated into one or more other embodiments in the same or similar manner, to be combined with features in other embodiments or substitute corresponding features in other embodiments. These technical solutions obtained through combination or substitution also should be considered as being covered within the scope of protection of the present disclosure.

What is claimed is:

1. A preparation method for preparing an embedded three-dimensional fan-out package structure, wherein the preparation method comprises following steps:
providing a multi-faceted pin chip, wherein pins of the multi-faceted pin chip are distributed in different positions of multiple side surfaces of the multi-faceted pin chip;
fabricating a chip module based on the multi-faceted pin chip, wherein pins of the chip module are located in a same plane;
bonding the chip module and an additional chip to a temporary carrier in a flip-mounting manner, so that the pins of the chip module and pins of the additional chip are located in a same plane and are connected to a same surface of the temporary carrier;
forming a plastic packaging layer on a side of the temporary carrier bonded with the chip module and the additional chip, so that the chip module and the additional chip are embedded in the plastic packaging layer;
removing the temporary carrier, so that the pins of the chip module and the pins of the additional chip are exposed from a first surface of the plastic packaging layer;
forming a redistribution layer on the first surface of the plastic packaging layer, wherein the redistribution layer comprises a wiring dielectric layer adjacent to the plastic packaging layer, a protective dielectric layer provided on a side of the wiring dielectric layer facing away from the chip modules and the additional chips, and an electrically conductive wiring layer embedded in the wiring dielectric layer and the protective dielectric layer and electrically connected to the chip module and the additional chip, and wherein the electrically conductive wiring layer comprises: lower pins respectively electrically connected to the pins of the chip module and the pins of the additional chip, interconnection lines connecting the pins of the chip module and the pins of the additional chip, first metal pillars respectively extending from the lower pins and the interconnection lines in a direction facing away from the chip module and the additional chip and electrically connected to corresponding lower pins and interconnection lines, and upper pins each formed at an end of the first metal pillars away from the chip module and the additional chip and electrically connected to the first metal pillars; and
forming electrically conductive solder balls and/or bumps on a side of the protective dielectric layer in the redistribution layer facing away from the chip module and the additional chip, wherein the electrically conductive solder balls and/or bumps pass through the protective dielectric layer to be electrically connected to the upper pins of the electrically conductive wiring layer.

2. The preparation method according to claim 1, wherein the step of fabricating a chip module based on the multi-faceted pin chip comprises following steps:
providing an insulating frame;
forming a first groove and a second groove extending through the insulating frame on the insulating frame;
providing an electrically conductive layer structure provided with a supporting substrate at a bottom;
forming a first bonding adhesive layer on a top of the electrically conductive layer structure opposite to the supporting substrate;
bonding the insulating frame formed with the first groove and the second groove onto a side of the first bonding adhesive layer opposite to the electrically conductive layer structure;
removing parts of the first bonding adhesive layer exposed via the first groove and the second groove, so as to expose parts of the electrically conductive layer structure facing open ends of the first groove and the second groove;
forming a metal material layer on a surface of a part of the electrically conductive layer structure facing an open end of the first groove, and forming an electrically conductive adhesive layer on a side of the metal material layer opposite to the electrically conductive layer structure;
bonding the multi-faceted pin chip in the first groove through the electrically conductive adhesive layer, so that pins on at least one side surface of the multi-faceted pin chip are electrically connected to the electrically conductive layer structure; and
filling the second groove with a metal material so as to form second metal pillars electrically connected to the electrically conductive layer structure, and forming metal leads at ends of the second metal pillars opposite to the electrically conductive layer structure, so as to transfer the pins of the multi-faceted pin chip to the same plane so that all the pins of the chip module are located in the same plane.

3. The preparation method according to claim 1, wherein the method further comprises following steps:
providing a heat dissipation frame after fabricating the chip module based on the multi-faceted pin chip;
accommodating the chip module and the additional chip fixedly in the heat dissipation frame, so that the pins of the chip module and the pins of the additional chip are located in the same plane;
bonding the chip module and the additional chip bonded in the heat dissipation frame to the temporary carrier in the flip-mounting manner, so that the pins of the chip module and the pins of the additional chip are connected to the same plane of the temporary carrier, and the heat dissipation frame is spaced apart from the temporary carrier; and
forming the plastic packaging layer on a side of the temporary carrier bonded with the chip module and the additional chip, so that the heat dissipation frame is embedded together with the chip module and the additional chip in the plastic packaging layer.

4. The preparation method according to claim 3, wherein the step of accommodating the chip module and the additional chip fixedly in the heat dissipation frame comprises following steps:
forming a chip module accommodating groove and a chip accommodating groove, each being closed at a bottom, on a same side of the heat dissipation frame;
providing a chip module bonding adhesive layer at a bottom of the chip module accommodating groove, and providing a chip bonding adhesive layer at a bottom of the chip accommodating groove; and
bonding the chip module in the chip module accommodating groove through the chip module bonding adhesive layer, and bonding the additional chip in the chip accommodating groove through the chip bonding adhesive layer, so that the pins of the chip module and the pins of the additional chip respectively protrude from open ends of the chip module accommodating groove and the chip accommodating groove and are located in the same plane.

5. The preparation method according to claim 4, wherein the heat dissipation frame is a copper frame.

6. The preparation method according to claim 1, wherein the step of fabricating a chip module based on the multi-faceted pin chip comprises following steps:
providing an insulating frame;
forming a first groove extending through the insulating frame on the insulating frame;
providing an electrically conductive layer structure provided with a supporting substrate at a bottom;
forming a first bonding adhesive layer on a top of the electrically conductive layer structure opposite to the supporting substrate;
bonding the insulating frame formed with the first groove to a side of the first bonding adhesive layer opposite to the electrically conductive layer structure;
forming a continuous metal material layer on a surface of a part of the first bonding adhesive layer facing an open end of the first groove and on a surface of a side wall of the first groove, and forming metal leads electrically connected to the metal material layer on a surface of the insulating frame surrounding the open end of the first groove, wherein the metal leads are configured to transfer the pins of the multi-faceted pin chip to the same plane so that all the pins of the chip module are located in the same plane;
forming an electrically conductive adhesive layer on a surface of a part of the metal material layer facing the open end of the first groove; and
bonding the multi-faceted pin chip in the first groove through the electrically conductive adhesive layer, so that pins on at least one side surface of the multi-faceted pin chip are electrically connected to the metal material layer.

7. The preparation method according to claim 1, wherein the step of fabricating a chip module based on the multi-faceted pin chip comprises following steps:
providing an electrically conductive layer structure provided with a supporting substrate at a bottom;
forming a first bonding adhesive layer on a top of the electrically conductive layer structure opposite to the supporting substrate;
forming an electrically conductive adhesive accommodating groove extending through the first bonding adhesive layer in the first bonding adhesive layer, so as to expose a part of the electrically conductive layer structure facing an open end of the electrically conductive adhesive accommodating groove;
filling an electrically conductive adhesive in the electrically conductive adhesive accommodating groove so as to form an electrically conductive adhesive layer; and
bonding the multi-faceted pin chip to the electrically conductive adhesive layer so as to form a chip stack, wherein pins on at least one side surface of the multi-faceted pin chip are electrically connected to the electrically conductive layer structure via the electrically conductive adhesive layer; and
the preparation method further comprises: before forming the redistribution layer on the first surface of the plastic packaging layer,
bonding the chip stack and the additional chip to the temporary carrier in a flip-mounting manner, so that pins of the chip stack located on a side opposite to the electrically conductive layer structure and the pins of the additional chip are located in the same plane and are connected to the same surface of the temporary carrier;
forming the plastic packaging layer on a side of the temporary carrier bonded with the chip stack and the additional chip, so that the chip stack and the additional chip are embedded in the plastic packaging layer;
removing the temporary carrier, so that the pins of the chip stack located on the side opposite to the electrically conductive layer structure and the pins of the additional chip are exposed from the first surface of the plastic packaging layer;
forming on the first surface of the plastic packaging layer communicating holes extending inwardly through the plastic packing layer and the first bonding adhesive layer located between the first surface and the electrically conductive layer structure of the chip stack around the chip stack; and
filling a metal material in the communicating holes so as to form guide metal pillars electrically connected to the electrically conductive layer structure, wherein the guide metal pillars transfer pins of the multi-faceted pin chip electrically connected to the electrically conductive layer structure to be located in the same plane as pins of the chip stack exposed from the first surface of the plastic packaging layer.

8. The preparation method according to claim 1, wherein the step of forming a redistribution layer on the first surface of the plastic packaging layer comprises following steps:
forming the lower pins and the interconnection lines from a metal material at positions on the first surface of the plastic packaging layer corresponding to pins of the chip module and pins of the additional chip exposed on the first surface;
forming the wiring dielectric layer, so that the wiring dielectric layer covers the lower pins, the interconnection lines and the first surface;
forming first through-holes at positions of the wiring dielectric layer corresponding to the lower pins and the interconnection lines, so that the first through-holes extend through the wiring dielectric layer up to the lower pins and the interconnection lines;
filling the first through-holes with a metal material to form the first metal pillars, so that the first metal pillars are electrically connected to the lower pins and the interconnection lines;
forming the upper pins from a metal material at ends of the first metal pillars opposite to the plastic packaging layer, so that the upper pins are electrically connected to the first metal pillars and partially protrude above the wiring dielectric layer;
forming the protective dielectric layer, so that the protective dielectric layer covers the upper pins and the wiring dielectric layer; and
forming blind vias at positions of the protective dielectric layer corresponding to the upper pins, so that the blind vias extend through the protective dielectric layer and make the upper pins exposed.

9. The preparation method according to claim 1, wherein the wiring dielectric layer and the protective dielectric layer are formed by spin coating or deposition.

10. The preparation method according to claim 1, wherein the electrically conductive solder balls are formed by solder balls prepared in advance or stencil printing and reflowing, and the bumps are formed by evaporation or sputtering.

11. The preparation method according to claim 8, wherein the grooves, the through-holes, the communicating holes and/or the blind vias are formed by at least one of photolithography and chemical etching.

12. The preparation method according to claim 8, wherein the lower pins, the interconnection lines and/or the upper pins are formed from a metal material by electroplating.

13. The preparation method according to claim 12, wherein the metal material comprises at least one of copper, aluminum, silver and gold.

14. An embedded three-dimensional fan-out package structure manufactured by the preparation method according to claim 1, wherein the embedded three-dimensional fan-out package structure comprises:
a plastic packaging layer, wherein the plastic packaging layer comprises a first surface and a second surface opposite to the first surface;
a chip module and an additional chip embedded in the first surface of the plastic packaging layer, wherein the chip module comprises multi-faceted pin chips, and the multi-faceted pin chips have pins distributed in different positions of multiple side surfaces, and the pins of the multi-faceted pin chips are transferred into a same plane by guide metal pillars, so that pins of the chip modules and pins of the additional chips are located in a same plane as the first surface of the plastic packaging layer;
a redistribution layer, wherein the redistribution layer is provided on the first surface of the plastic packaging layer, and the redistribution layer comprises a wiring dielectric layer adjacent to the plastic packaging layer, a protective dielectric layer provided on a side of the wiring dielectric layer facing away from the chip modules and the additional chips, and an electrically conductive wiring layer embedded in the wiring dielectric layer and the protective dielectric layer and electrically connected to the chip module and the additional chip, and wherein the electrically conductive wiring layer comprises: lower pins respectively electrically connected to the pins of the chip module and the pins of the additional chip, interconnection lines connecting the pins of the chip module and the pins of the additional chip, first metal pillars respectively extending from the lower pins and the interconnection lines in a direction facing away from the chip module and the additional chip and electrically connected to corresponding lower pins and interconnection lines, and upper pins each formed at an end of the first metal pillars away from the chip module and the additional chip and electrically connected to the first metal pillars; and
electrically conductive solder balls and/or bumps, wherein the electrically conductive solder balls and/or the bumps are provided on a side of the protective dielectric layer in the redistribution layer facing away from the chip module and the additional chip and pass through the protective dielectric layer to be electrically connected to the upper pins of the electrically conductive wiring layer.

15. The embedded three-dimensional fan-out package structure according to claim 14, wherein the chip module comprises:
an electrically conductive layer structure provided with a supporting substrate at a bottom;
a first bonding adhesive layer formed on a top of the electrically conductive layer structure opposite to the supporting substrate;
an insulating frame bonded onto a side of the first bonding adhesive layer opposite to the electrically conductive layer structure, wherein the insulating frame is formed with a first groove and a second groove penetrating the insulating frame, and a first bonding adhesive layer through-hole and a second bonding adhesive layer through-hole penetrating the first bonding adhesive layer are respectively formed in parts of the first bonding adhesive layer facing open ends of the first groove and the second groove;
a metal material layer filled in the first bonding adhesive layer through-hole and electrically connected to the electrically conductive layer structure;
an electrically conductive adhesive layer formed on a side of the metal material layer opposite to the electrically conductive layer structure;
the multi-faceted pin chip bonded in the first groove through the electrically conductive adhesive layer, wherein pins on at least one side surface of the multi-faceted pin chip are electrically connected to the electrically conductive layer structure via the electrically conductive adhesive layer and the metal material layer; and
second metal pillars filled in the second groove of the insulating frame and the second bonding adhesive layer through-hole, and metal leads formed at ends of the second metal pillars opposite to the electrically conductive layer structure, and configured to transfer the pins of the multi-faceted pin chip to the same plane, so that all the pins of the chip module are located in the same plane.

16. The embedded three-dimensional fan-out package structure according to claim 14, wherein the embedded three-dimensional fan-out package structure further comprises a heat dissipation frame, wherein the heat dissipation frame is embedded together with the chip module and the additional chip in the plastic packaging layer, wherein
the heat dissipation frame comprises a chip module accommodating groove and a chip accommodating groove, each being closed at a bottom, formed on a same side of the heat dissipation frame, a chip module bonding adhesive layer is provided at a bottom of the chip module accommodating groove, and a chip bonding adhesive layer is provided at a bottom of the chip accommodating groove, wherein the chip module is bonded in the chip module accommodating groove through the chip module bonding adhesive layer, the additional chip is bonded in the chip accommodating groove through the chip bonding adhesive layer, and the pins of the chip module and the pins of the additional chip respectively protrude from open ends of the chip module accommodating groove and the chip accommodating groove and are located in the same plane.

17. The embedded three-dimensional fan-out package structure according to claim 16, wherein the heat dissipation frame is a copper frame.

18. The embedded three-dimensional fan-out package structure according to claim 14, wherein the chip module comprises:
an electrically conductive layer structure provided with a supporting substrate at a bottom;
a first bonding adhesive layer formed on a top of the electrically conductive layer structure opposite to the supporting substrate;
an insulating frame bonded onto a side of the first bonding adhesive layer opposite to the electrically conductive layer structure, wherein the insulating frame is formed with a first groove penetrating the insulating frame;
a continuous metal material layer formed on a surface of a part of the first bonding adhesive layer facing an open end of the first groove and on a surface of a side wall of the first groove, and metal leads formed on a surface of the insulating frame surrounding the open end of the first groove and electrically connected to the metal material layer;
an electrically conductive adhesive layer formed on a surface of a part of the metal material layer facing the open end of the first groove; and
the multi-faceted pin chip, wherein the multi-faceted pin chip is bonded in the first groove through the electrically conductive adhesive layer, so that pins on at least one side surface of the multi-faceted pin chip are electrically connected to the metal material layer.

19. The embedded three-dimensional fan-out package structure according to claim 14, wherein the chip module comprises:
a chip stack, wherein the chip stack comprises:
an electrically conductive layer structure provided with a supporting substrate at a bottom;
a first bonding adhesive layer formed on a top of the electrically conductive layer structure opposite to the supporting substrate, wherein an electrically conductive adhesive accommodating groove penetrating the first bonding adhesive layer is formed in the first bonding adhesive layer;
an electrically conductive adhesive layer formed in the electrically conductive adhesive accommodating groove; and
the multi-faceted pin chip, wherein the multi-faceted pin chip is bonded onto the electrically conductive layer structure through the electrically conductive adhesive layer, so that pins on at least one side surface of the multi-faceted pin chip are electrically connected to the electrically conductive layer structure, and pins located on a side of the multi-faceted pin chip opposite to the electrically conductive layer structure are exposed from the first surface of the plastic packaging layer and located in the same plane as the first surface; and
guide metal pillars provided around the chip stack, wherein the guide metal pillars transfer pins of the multi-faceted pin chip electrically connected to the electrically conductive layer structure to be located in the same plane as pins of the chip stack exposed from the first surface of the plastic packaging layer, wherein the guide metal pillars extend from the electrically conductive layer structure and pass through first bonding adhesive layer through-holes formed in the first bonding adhesive layer and the plastic packaging layer between the first surface and the electrically conductive layer structure.

20. The embedded three-dimensional fan-out package structure according to claim 15, wherein the metal material comprises at least one of copper, aluminum, silver and gold.
